(19) United States
(12) Patent Application Publication
(10) Pub. No.: US 2015/0047556 A1
(43) Pub. Date: Feb. 19, 2015

(54) Method for Purifying Silicon

(71) Applicant: COMMISSARIAT AL'ENERGIE ATOMIQUE ET AUX ENERGIES ALTERNATIVES, Paris (FR)

(72) Inventors: Jean-Paul Garandet, Saint Cloud (FR); Mickael Albaric, La Motte Servolex (FR); Claire Audoin, Saint Ismier (FR); Denis Chavrier, Chambery (FR); Etienne Pihan, La Motte Servolex (FR)

(21) Appl. No.: 14/371,874

(22) PCT Filed: Jan. 11, 2013
(86) PCT No.: PCT/IB2013/050275

§ 371 Date: Jul. 11, 2014

(30) Foreign Application Priority Data
Jan. 13, 2012 (FR) 1250364

(51) Int. Cl. C01B 33/037; C30B 11/00

(52) U.S. Cl. CPC C01B 33/037; C30B 11/007; C30B 29/06
USPC 117/83; 117/81

(57) ABSTRACT

The present invention relates to a method for purifying silicon, comprising at least the following steps: c) providing a container (1) that comprises silicon (10) in molten state, the container (1) having a longitudinal axis (X) and the silicon (10) in molten state defining a free surface (11) on the side opposite the bottom (4) of the container (1); d) imposing on the silicon (10) in molten state conditions that are favourable for the solidification thereof, the mean temporal velocity for the duration of step b) of propagating the solidification front (13) of the silicon, measured along the longitudinal axis (X) of the container (1), being no lower than 5 μm/s, preferably 10 μm/s; said method being characterised in that at least one stirring system (30) imposes, during all or part of step b), a flow of silicon (10) in molten state with a Reynolds number comprised between 3 10⁴ and 3 10⁶, preferably between 10⁵ and 10⁶.

The present invention relates to processes for purifying silicon.

Photovoltaic cells are mainly manufactured from single-crystal or polycrystalline silicon in sectors that implement the solidification of ingots from a liquid bath contained in a crucible.

The feedstock, used as raw material, is conventionally produced via a process of distilling a chlorine-containing precursor obtained from metallurgical grade silicon. This process is very effective as regards purification, but costly in terms of financial investment and power consumption.

For a number of years, alternative processes have been proposed for the manufacture of solar-grade silicon on the basis of processes based on metallurgical techniques.

Specifically, directional solidification processes allowing impurities to be segregated and, therefore, the original feedstock to be purified, are known.

Regarding silicon purification, the technique may be well-suited to metal impurities (Fe, Cr, Ni, etc.) the segregation coefficients of which are very small compared to unity.

It is recalled that the segregation coefficient k of an impurity measures the ratio between its concentrations between the solid phase and liquid phase at the solidification interface.

A low segregation coefficient therefore makes it possible to envision a very effective purification by segregation.

Moreover, it is known that a high solidification speed tends to lead to a poor segregation.

However, it would also be desirable to employ a high solidification speed, typically higher than 5 μm/s, in order to decrease the cost of these silicon purification processes.

Thus, it is known to use external stirring systems in processes employing high solidification speeds. However, on account of the sizes of the liquid baths used industrially and the convection levels required for such solidification speeds, the flow may be unsteady or even turbulent.

Thus, variations that are also unsteady in growth speed and impurity incorporation may be obtained. Such conditions may result, on the scale of the whole ingot, in a degradation in the capacity to segregate impurities.

This is understandable from a qualitative point of view as, under unstable conditions, most of the ingot is solidified at moments in the cycle when the solidification speed is higher than average and therefore when the incorporation of impurities is maximal. Such a teaching is discussed in the publication F. Z. Haddad, J. P. Garandet, D. Henry, H. Ben Hadid, J. Crystal Growth 204 (1999) 213.

Therefore, there is a need to provide a process for purifying silicon ensuring a good segregation under high solidification speed conditions.

The present invention aims to meet the aforementioned need.

According to a first aspect, the present invention relates to a process for purifying silicon comprising at least steps consisting in:
a) providing a container containing molten silicon, the container having a longitudinal axis and the molten silicon defining on the side opposite the bottom of the container a free surface; and
b) imposing on the molten silicon conditions that promote its solidification, the propagation speed of the solidification front of the silicon time averaged over the duration of step b) and measured along the longitudinal axis of the container being higher than or equal to 5 μm/s and preferably 10 μm/s,
   said process being characterized in that at least one stirring system imposes, throughout all or some of step b), a flow of molten silicon of Reynolds number comprised between 3×10⁴ and 3×10⁶ and preferably between 1×10⁵ and 1×10⁶.

The longitudinal axis of the container denotes the line joining all the barycenters of cross sections through said container (including the walls of the container). The longitudinal axis may be an axis of symmetry of the container. The longitudinal axis of the container is preferably rectilinear, and may be contained in a plane, which plane may be a plane of symmetry for certain, even all of the cross sections of said container.

The Reynolds number Re of the flow of molten silicon imposed by the stirring system is given by the relationship:

$$Re = \frac{V \times L}{v} .$$

In this formula:
V denotes the maximum instantaneous velocity of the molten silicon fluid particles made to move by the stirring system;
L denotes the smallest transverse dimension of the container; and
v denotes the kinematic viscosity of the molten silicon, for example 3.5×10⁻⁷ m²s such as indicated in the publication by Sasaki et al. Jpn J. Appl. Phys. 34, 3432 (1995).

Thus, in the example where the stirring system is, as will be detailed below, a rotary propeller, V corresponds to the instantaneous speed of the distal ends of the propeller.

The inventors have observed that imposing, throughout all or some of step b), on the molten silicon, a flow with a particular Reynolds number advantageously allows an effective segregation to be obtained, thus leading to the obtainment of particularly pure solid silicon despite the high solidification speeds employed.

Without wanting to be tied to one particular theory, the inventors consider that the Reynolds numbers selected in the context of processes according to the invention advantageously allow a viscous hydrodynamic boundary layer to be obtained that is thicker than the solutal boundary layer.

Thus, with respect to the segregation of impurities, the flow may therefore be considered as viscous, thus avoiding the problems with transient impurity incorporation mentioned in the prior art.

Moreover, due to its action on the temperature field, the stirring system may advantageously make it possible to increase locally thermal gradients in the vicinity of the solidification front, while reducing them in the core of the liquid bath. This decrease in the thermal gradient in the core allows the maximum temperature of the bath to be decreased, thus decreasing the solubilization of impurities present in the walls of the container and/or the optional coating present on said walls as will be detailed below.

Previously to step a), the solid silicon may be introduced into the recipient and then be melted therein. As a variant, the process comprises a step of introducing into the container molten silicon.

The molten silicon may or may not make contact with the walls of the container. Thus, in one embodiment, the walls of the container may be coated with a nonstick coating.

The stirring system may advantageously be present in the molten silicon throughout all or some of step b), the forced flow of molten silicon being, in this case, generated by making said stirring system move.

In this case, the movement of the stirring system preferably comprises and especially consists of a rotary movement.

The rotary movement may occur about an axis of rotation making, with at least one portion of the longitudinal axis of the container, an angle smaller than 45°, especially than 30° and particularly than 15°, the axis of rotation especially being co-linear with the longitudinal axis of the container.

Preferably, the stirring system present in the molten silicon throughout all or some of step b), moves, throughout all or some of step b), in rotation at a speed comprised between 5 and 200 revolutions/minute, and preferably between 10 and 100 revolutions/minute.

The stirring system makes it possible, for example, to obtain, throughout all or some of step b), a maximum instantaneous velocity for the molten silicon fluid particles of between 1 and 100 cm/s and especially 5 and 50 cm/s.

The direction of rotation of the stirring system may be modified in step b).

The stirring system may be introduced into the molten silicon before the start of the solidification of the silicon.

The stirring system may be introduced into the molten silicon and made to rotate therein before the start of the solidification of the silicon.

The stirring system is preferably a mechanical stirring system.

The stirring system for example comprises a propeller, a vane and/or a disc.

The stirring system particularly preferably comprises a propeller or a vane which may, throughout all or some of step b), be present in the molten silicon and made to move in rotation.

The stirring system may be moved relative to the container, especially along its longitudinal axis, in step b).

The flow of molten silicon may be generated by the action of a plurality of stirring systems.

The stirring may be stopped before the silicon has completely solidified.

The stirring system may be withdrawn from the molten silicon before the silicon has completely solidified.

As a variant, the stirring system is at no moment in step b) present in the molten silicon. The stirring system may, in this case, comprise an alternating, traveling or rotating electromagnetic field generator, the flow of molten silicon being, in step b), generated by applying said electromagnetic field. Examples of a forced flow formed via the generation of an electromagnetic field are described in the article by Mitric et al, J. Crystal Growth, 310 (2008), 1424 for an alternating field, in the article by Rudolph, 2008, J. Crystal Growth, 310, 1298 for a travelling field, and in the article by Dold et al, J. Crystal Growth, 231 (2001), 95 for a rotating field.

The process may comprise a step c) of cooling, especially down to room temperature, the solid silicon obtained at the end of step b).

The expression “room temperature” denotes a temperature of 20° C.±5° C.

The process may comprise a step d) of recovering the purified solid silicon obtained at the end of step c).

Step d) advantageously comprises a step of removing material rich in compounds other than silicon.

This removing step may be carried out by cutting off lateral, top and bottom portions of the ingot obtained.

Independently or in combination with the above, the invention relates, according to another of its aspects, to a process for purifying silicon comprising at least steps consisting in:
a) providing a container containing molten silicon, the container having a longitudinal axis and the molten silicon defining on the side opposite the bottom of the container a free surface; and
b) imposing on the molten silicon conditions that promote its solidification, the propagation speed of the solidification front of the silicon time averaged over the duration of step b) and measured along the longitudinal axis of the container being higher than or equal to 5 μm/s and preferably 10 μm/s,

said process being characterized in that at least one stirring system imposes, throughout all or some of step b), a flow of molten silicon making it possible to obtain, throughout all or some of step b), a ratio

$$\frac{{k}_{eff}}{k}$$

of the effective and equilibrium segregation coefficients of compounds other than silicon lower than 2 and preferably than 1.25.

The effective segregation coefficient k_{eff} of a given species is related to the equilibrium segregation coefficient k of the same species by the following relationship:

$${k}_{eff} = \frac{k}{1 - ( 1 - k ) \frac{δ {V}_{l}}{D}} .$$

In the above relationship:
δ denotes the thickness of the solutal boundary layer in front of the solidification front obtained in the presence of the flow of molten silicon imposed by the stirring system;
V₁ denotes the propagation speed of the solidification front of the silicon measured along the longitudinal axis of the container; and
D denotes the diffusion coefficient of the species in question.

Independently or in combination with the above, the invention relates, according to another of its aspects, to a process for purifying silicon comprising at least steps consisting in:
a) providing a container containing molten silicon, the container having a longitudinal axis and the molten silicon defining on the side opposite the bottom of the container a free surface; and
b) imposing on the molten silicon conditions that promote its solidification, the propagation speed of the solidification front of the silicon time averaged over the duration of step b) and measured along the longitudinal axis of the container being higher than or equal to 5 μm/s and preferably 10 μm/s,

said process being characterized in that at least one stirring system imposes, throughout all or some of step b), a flow of molten silicon making it possible to obtain, throughout all or some of step b), a ratio

$$\frac{δ {V}_{l}}{D}$$

for compounds other than silicon smaller than 0.5 and preferably than 0.2, the quantities δ, V, and D being such as defined above.

The processes defined above may advantageously make it possible to obtain purified solid silicon having a silicon concentration by weight higher than or equal to 99.99% and preferably to 99.999%.

Protocol for Measuring the Propagation Speed of the Solidification Front of the Silicon

The propagation speed of the solidification front of the silicon, measured along the longitudinal axis of the container, is evaluated by mechanical probing of the solid phase through the liquid phase by means of a rod made of refractory ceramic. More precisely, the operator introduces the rod, for example of silica, into the molten bath during the solidification and makes contact with the solid/liquid interface, in order to measure the position of the interface. This operation is carried out a number of times during the solidification and makes it possible to calculate a time-averaged speed of the interface. This measuring method is known to those skilled in the art and widely used in the industry due to its robustness and its simplicity.

Determination of the Segregation Coefficients

Segregation Coefficient k

For a given impurity, the segregation coefficient k is tabulated in the reference F. A. Trumbore, Bell Syst. Tech. J., vol 39, p205, 1960.

Effective Segregation Coefficient k_{eff}

The effective segregation coefficient is measured via fitting of the concentration profiles measured for example by atomic absorption spectroscopy (AAS) or inductively coupled plasma mass spectrometry (ICP-MS), carried out a posteriori on the solidified ingots.

### DESCRIPTION OF THE FIGURES

The invention will be better understood on reading the following detailed description of nonlimiting example embodiments thereof and on examining the appended drawings, in which:

FIG. 1 schematically and partially illustrates a section of a container usable in the context of the present invention; and

FIG. 2 schematically and partially illustrates the silicon solidifying step implemented in the context of processes according to the invention.

FIG. 3 shows a graph of aluminum concentration as a function of solidified silicon height, obtained in the context of the invention and in a reference trial without stirring.

In the appended drawings, the actual proportions of the various elements have not necessarily been respected, for the sake of clarity.

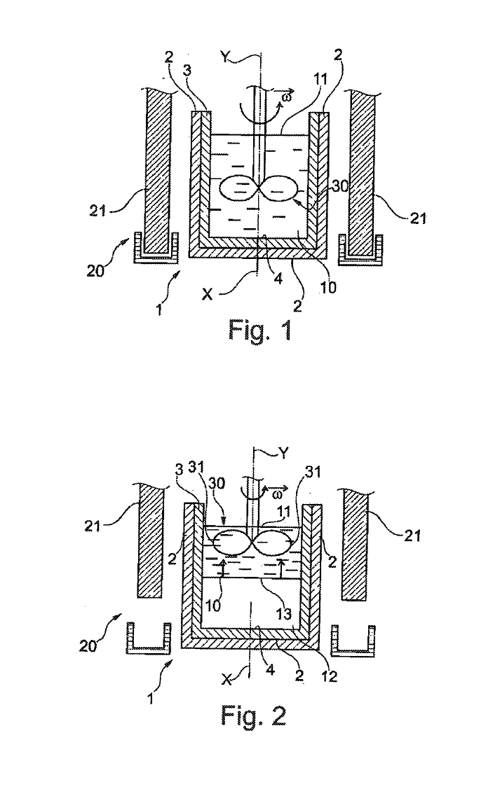

FIG. 1 illustrates a container 1 of longitudinal axis X the internal walls 2 of which have been coated with a nonstick coating 3. The container 1 has a bottom 4.

The container 1 used may, for example, be a silicate crucible and the nonstick coating 3 may consist of a silicon nitride layer.

The container 1 contains, as illustrated, molten silicon 10 defining a free surface 11 on the side opposite the bottom 4 of the container 1. The molten silicon 10 may be obtained by melting solid silicon initially present in the container 1. As a variant, the silicon may be melted under vacuum above the container 1 and the container 1 may be filled by injection or suction.

Heating means (not shown) make it possible to maintain the silicon 10 in its molten state by subjecting the latter to a temperature above its melting point.

A stirring system taking the form of a propeller 30 is positioned in the molten silicon 10 and is, as illustrated, made to move in rotation about the axis of rotation Y which is co-linear with the longitudinal axis X. The scope of the invention is not departed from if the axis Y forms a nonzero angle with the axis X.

The propeller 30 may, as illustrated, before the start of the solidification of the silicon be introduced substantially at midheight into the container 1.

As regards the problem of heat removal, a thermally insulating system 20 especially comprising shutters 21 that are insulating when in a closed position is, for example, present in order to decrease heat exchange before the start of the solidification of the silicon.

FIG. 2 illustrates the state of the system at a given instant in step b). As illustrated, the insulating shutters 21 are in an open position thus allowing heat exchange and, as a result, the solidification of the silicon.

The silicon solidification front 13, separating molten silicon 10 and solid silicon 12, propagates at an average speed, measured along the longitudinal axis X of the container 1, higher than or equal to 5 μm/s and preferably than 10 μm/s.

As illustrated, the solidification front 13 progresses from the bottom 4 of the container 1 toward the free surface 11 in step b).

It is within the ability of those skilled in the art to adjust the heat transfer properties in order to obtain the values desired for the propagation speed of the silicon solidification front.

As illustrated in FIG. 2, the propeller 30 has been moved relative to the container 1 along the longitudinal axis X of the latter, this movement having taken place during the solidification of the silicon, and imposes a maximum velocity on the fluid particles located in the vicinity of its distal ends 31.

### EXAMPLES

### Example 1

A charge of silicon of about 60 kg, taking the form of centimeter-sized chunks, is introduced into a Vesuvius® silica crucible having internal dimensions of 39×39×39 cm, on which a nonstick coating of silicon nitride had been deposited beforehand. The silicon used may be metallurgical grade silicon especially comprising 150 ppm by weight Al.

The assembly is then introduced into the solidification device, a vertical furnace employing gradient freeze technology and having heating elements (graphite resistors) located at the top and on the sides of the crucible. The silicon is first raised to a temperature of 1430° C. in order to ensure it is completely melted.

The mechanical stirrer (7.5 cm long silica vane referenced DA 00194 manufactured by Vesuvius) is then introduced into the molten bath, positioned at midheight in the bath and made to rotate at an angular velocity of 15 revolutions/minute. The Reynolds number obtained is here 1.3×10⁵.

In order to initiate solidification, extraction of heat from the bottom is then increased by controllably opening insulating shutters.

When about half the silicon has been solidified, the stirrer is raised and positioned 2 cm under the interface between the liquid and the atmosphere of the chamber, while maintaining the rotation at an angular velocity of 15 revolutions/minute.

When the solid/liquid interface approaches less than 4 cm from the liquid/vapor interface, the stirrer is raised out of the bath and the rotation is stopped. Complete solidification of the 25 cm high ingot is achieved in about 7 hours, the average solidification speed is therefore 3.6 cm/h or equivalently 10 μm/s. In the growth regime, the power consumed by the furnace is about 38 kW.

The heating power is then decreased and the ingot brought to room temperature and demolded from the crucible.

The Al concentration profile in the solidified ingot is then measured by inductively coupled plasma mass spectrometry (ICP-MS). Fitting Scheil's law to the solidified fraction gives a value of 2.4×10⁻³. Divided by the reference value for the equilibrium segregation coefficient (k=2×10⁻³), the ratio k_{eff} k is 1.2.

Scheil's law is conventionally used as a reference by those skilled in the art to model chemical segregation profiles in directed solidification processes. From a mathematical point of view, the underlying assumptions are to assume that the liquid may at each instant be considered to be uniform in concentration, and that diffusion in the solid may be neglected. Under these conditions, Scheil's law represents a minimum in the amount of impurities incorporated in the solidified fraction and therefore an optimum in terms of purification.

### Example 2

A charge of silicon of about 60 kg, taking the form of centimeter-sized chunks, is introduced into a Vesuvius® silica crucible having internal dimensions of 39×39×39 cm, on which a nonstick coating of silicon nitride had been deposited beforehand. The silicon used is metallurgical grade silicon especially comprising 2000 ppm by weight Fe. The assembly is then introduced into the solidification device, a vertical furnace employing gradient freeze technology and having heating elements (graphite resistors) located at the top and on the sides of the crucible.

The silicon is first raised to a temperature of 1430° C. in order to ensure it is completely melted. The mechanical stirrer (silica vane referenced DA 00194 manufactured by Vesuvius) is then introduced into the molten bath, positioned at midheight in the bath and made to rotate at an angular velocity of 70 revolutions/minute (namely a Reynolds number of 6×10⁵).

In order to initiate solidification, extraction of heat from the bottom is then increased by controllably opening insulating shutters. In the growth regime, the power consumed by the furnace is about 38 kW. When about half the silicon has been solidified, the stirrer is raised and positioned 2 cm under the interface between the liquid and the atmosphere of the chamber, while maintaining the rotation at an angular velocity of 70 revolutions/minute.

When the solid/liquid interface approaches less than 4 cm from the liquid/vapor interface, the stirrer is raised out of the bath and the rotation is stopped.

Complete solidification of the 25 cm high ingot is achieved in about 7 hours, the average solidification speed is therefore 3.6 cm/h or equivalently 10 μm/s. The heating power is then decreased and the ingot brought to room temperature and demolded from the crucible.

The Fe concentration profile in the solidified ingot is then measured by inductively coupled plasma mass spectrometry (ICP-MS). Fitting Scheil's law to the solidified fraction gives a value of 1.1×10⁻⁵. Divided by the reference value for the equilibrium segregation coefficient (k=1×10), the ratio k_{eff}/k is 1.1.

### Example 3

Characterization of the advantageous effect of the stirring according to the invention on purification by unidirectional solidification of silicon.

For the sake of comparison, a purification without application of stirring was carried out conjointly with a purification according to the invention.

The starting silicon charge is in both cases contaminated with 500 ppm by weight Al.

The experimental conditions employed in terms of the crucible used, of the grade, amount and form of the feedstock silicon, of the solidifying device and heating temperature are similar to those employed in examples 1 and 2.

As regards the purification according to the invention, the stirring system used is of mechanical type comprising a vane identical to that of examples 1 and 2. Said vane is introduced into the molten bath, positioned at midheight in the bath, and made to rotate at an angular velocity of 50 revolutions/minute (namely a Reynolds number of 2.1×10⁵). In order to initiate solidification, extraction of heat from the bottom of the furnace is then increased by controllably opening insulating shutters. In the growth regime, the power consumed by the furnace is about 38 kW. When about half the silicon has been solidified, the stirrer is raised and positioned 2 cm under the interface between the liquid and the atmosphere of the chamber, while maintaining the rotation at an angular velocity of 50 revolutions/minute. When the solid/liquid interface approaches less than 4 cm from the liquid/vapor interface, the stirrer is raised out of the bath and the rotation is stopped.

The process conditions (except of course those relating to the vane system) are identical in the solidification experiment without stirring.

In the two types of experiment carried out (according to the invention or without the stirring system), complete solidification of the 25 cm high ingot is achieved in about 7 hours, the average solidification speed is therefore 3.6 cm/h or equivalently 10 μm/s, as in examples 1 and 2. The heating power is then decreased and the ingot brought to room temperature and demolded from the crucible.

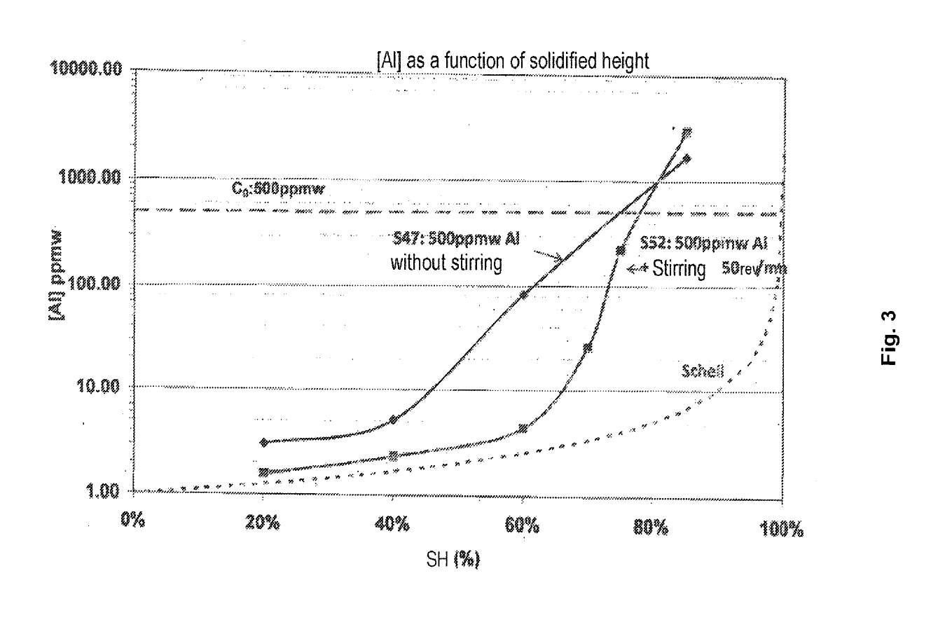

FIG. 3 shows curves representing the aluminum concentration as a function of solidified silicon height.

By way of reference, the curve modeling the solidification of the silicon according to Scheil's law is also shown therein.

When a stirring system is not used, it may be seen that the curve representing the variation of the aluminum concentration as a function of solidification height is very different from the curve representing Scheil's segregation law.

In contrast, the graph in FIG. 3 shows that mechanical stirring with a vane maintained at an angular velocity of rotation of 50 revolutions/minute, such as to obtain a Reynolds number of 2.1×10⁵, clearly makes it possible to approach Scheil's segregation law.

Unless otherwise mentioned, the expression “comprising/containing a” must be understood to mean “comprising/containing at least one”.

Unless otherwise mentioned, the expression “comprised between . . . and . . . ” must be understood to include the limiting values.

Unless otherwise mentioned, the expression “ranging from . . . to . . . ” must be understood to include the limiting values.

1-17. (canceled)

18. A process for purifying silicon comprising:
providing a container containing molten silicon, the container having a longitudinal axis (X) and the molten silicon defining on the side opposite a bottom of the container a free surface; and
imposing on the molten silicon conditions that promote its solidification with a propagation speed of a solidification front of the silicon higher than or equal to 5 μm/s, time averaged over the duration of solidification and measured along the longitudinal axis, while stirring the molten silicon with at least one stirring system throughout all or part of this step at a flow of molten silicon having a Reynolds number between 3×10⁴ and 3×10⁶ to obtain purified solid silicon.

19. The process of claim 18, wherein the flow of molten silicon is generated by making the stirring system move.

20. The process of claim 19, wherein the movement of the stirring system comprises a rotary movement.

21. The process of claim 20, wherein the rotary movement occurs about an axis (Y) of rotation making, with at least one portion of the longitudinal axis (X), an angle smaller than 45° with the longitudinal axis (X) of the container.

22. The process of claim 20, wherein the rotary movement occurs about an axis (Y) of rotation being, with at least one portion of the longitudinal axis (X), co-linear with the longitudinal axis (X) of the container.

23. The process of claim 20, wherein a direction of rotation of the stirring system is modified during stirring.

24. The process of claim 19, wherein the stirring system is a mechanical stirring system.

25. The process of claim 18, wherein the stirring system is moved relative to the container.

26. The process of claim 18, wherein the solidification front progresses from the bottom of the container toward the free surface.

27. The process of claim 18, wherein the internal walls of the container are coated with a nonstick coating.

28. The process of claim 18, wherein the stirring is stopped before the silicon has completely solidified.

29. The process of claim 18, wherein the flow of molten silicon is generated by the action of a plurality of stirring systems.

30. The process of claim 18, wherein solid silicon is introduced into the container and then melted therein.

31. The process of claim 18, wherein a ratio
$$\frac{{k}_{eff}}{k}$$
of the effective and equilibrium segregation coefficients of compounds other than silicon is, throughout all or part of the solidification is lower than 2.

32. The process of claim 18, further comprising cooling the purified solid silicon obtained.

33. The process of claim 32, further comprising recovering the purified solid silicon.

34. The process of claim 33, wherein the purified solid silicon has a silicon concentration by weight higher than or equal to 99.99%.

35. The process of claim 33, further comprising removing material enriched with compounds other than silicon.

36. The process of claim 18, wherein the propagation speed of the solidification front of the silicon, time averaged over the duration of solidification and measured along the longitudinal axis (X) of the container is higher than or equal to 10 μm/s.

37. The process of claim 18, wherein the flow of molten silicon has a Reynolds number between 1×10⁵ and 1×10⁶.
